(19) United States
(12) Patent Application Publication
(10) Pub. No.: US 2005/0285108 A1
(43) Pub. Date: Dec. 29, 2005

(54) Pixel circuit and display device having improved transistor structure

(76) Inventor: Woong-Sik Choi, Kyunggi-do (KR)

Correspondence Address: McGuireWoods LLP, Suite 1800, 1750 Tysons Boulevard, McLean, VA, 22102, US

(21) Appl. No.: 11/158,101

(22) Filed: Jun. 22, 2005

(30) Foreign Application Priority Data
Jun. 25, 2004 (KR) 2004-48314

(51) Int. Cl. H01L 29/04

(52) U.S. Cl. 257/59

(57) ABSTRACT

Disclosed is a transistor and a pixel circuit and organic light emitting display including the transistor. The pixel circuit includes a first switching device transmitting a data signal in response to a selection signal, a storage capacitor storing a voltage corresponding to the transmitted data signal, and a driving transistor supplying a current corresponding to the voltage stored in the storage capacitor for driving an organic light emitting device. The driving transistor comprises a semiconductor layer including a substantially rectangular ring-shaped channel region and a source region and a drain region connected to opposite comers of the channel region, and a gate electrode facing the channel region across an insulating layer.

### CROSS-REFERENCE TO RELATED APPLICATION

This application claims priority to and the benefit of Korean Patent Application No. 10-2004-0048314, filed on Jun. 25, 2004, which is hereby incorporated by reference for all purposes as if fully set forth herein.

### BACKGROUND

1. Field of the Invention

The present invention relates to a transistor, a pixel circuit and a display device, and more particularly, to a pixel circuit and display device having more uniform driving transistors, thereby improving picture quality.

2. Discussion of the Background

Generally, an active matrix type organic light emitting display comprises a thin film transistor (TFT) array in a panel. More specifically, the active matrix type organic light emitting display may comprise at least two TFTs in a pixel representing red, green, blue or white. The two TFTs may include a switching transistor to control each pixel's operation and a driving transistor to drive an organic light-emitting device.

An active matrix type organic light emitting display may have a random mura and a line mura, thereby deteriorating picture balance. The mura represents apparent uniformity defects of a flat panel display (FPD). The random mura may increase on the screen when the driving transistor's characteristics are less uniform, and a non-uniform excimer laser annealing (ELA) process may create a line mura.

Particularly, the ELA process, which may be used to fabricate a polycrystalline silicon (polysilicon) TFT, may have non-uniform energy distribution with respect to the processing direction and the excimer laser beam itself, thereby decreasing the uniformity of the driving transistors.

In a conventional active matrix type organic light emitting display, a compensation circuit may be included in each pixel circuit to compensate for a threshold voltage of the driving transistor, thereby compensating for the problem in the uniformity of the TFT panel fabricated using the ELA process.

However, adding a compensation circuit to the pixel circuit complicates the pixel circuit structure and decreases the aperture ratio. Therefore, it may be difficult to fabricate the conventional active matrix type organic light emitting display.

### SUMMARY OF THE INVENTION

The present invention provides a TFT, in which a current path may be altered from a defective channel to another channel of the TFT, so that the entire current may remain substantially constant.

The present invention also provides a pixel circuit and a display device comprising a TFT formed with an insulating island in a channel region so as to improve picture quality.

Additional features of the invention will be set forth in the description which follows, and in part will be apparent from the description, or may be learned by practice of the invention.

The present invention discloses a pixel circuit of an organic light emitting display, including a first switching device transmitting a data signal in response to a selection signal; a storage capacitor storing a voltage corresponding to the transmitted data signal; and a driving transistor supplying a current corresponding to the voltage stored in the storage capacitor for driving an organic light emitting device. The driving transistor includes a semiconductor layer having a substantially rectangular ring-shaped channel region and a source region and a drain region respectively connected to opposite comers of the channel region, and a gate electrode facing the channel region across an insulating layer.

The present invention also discloses an organic light emitting display including a data line to transmit a data signal, a scan line to transmit a scan signal, and a pixel circuit that is formed in a region defined by two adjacent data lines and two adjacent scan lines. The pixel circuit includes a first switching device transmitting the data signal in response to the selection signal, a storage capacitor storing a voltage corresponding to the transmitted data signal, and a driving transistor supplying a current corresponding to the voltage stored in the storage capacitor for driving an organic light emitting device. The driving transistor includes a semiconductor layer having a substantially rectangular ring-shaped channel region and a source region and a drain region connected to opposite comers of the channel region, respectively, and a gate electrode facing the channel region across an insulating layer.

The present invention also discloses a transistor including a semiconductor layer that is formed on a substrate and comprises a substantially rectangular ring-shaped channel region, and a source region and a drain region connected to opposite comers of the channel region, respectively; an insulating layer formed contacting the channel region; and a gate electrode facing the channel region across the insulating layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a plan view showing a driving transistor according to an exemplary embodiment of the present invention.

FIG. 2 is a plan view showing the driving transistor of FIG. 1 with a defect in a channel region.

FIG. 3A is a sectional view showing the driving transistor along line I-I of FIG. 1.

FIG. 3B is a sectional view showing the driving transistor along line II-II of FIG. 1.

FIG. 4 is a layout of a pixel comprising a driving transistor according to an exemplary embodiment of the present invention.

FIG. 5 is a sectional view showing the pixel along line IV-IV of FIG. 4.

FIG. 6 is a circuit diagram showing a pixel comprising the driving transistor according to an exemplary embodiment of the present invention.

FIG. 7 is a schematic view showing an organic light emitting display according to an exemplary embodiment of the present invention.

### DETAILED DESCRIPTION OF THE ILLUSTRATED EMBODIMENTS

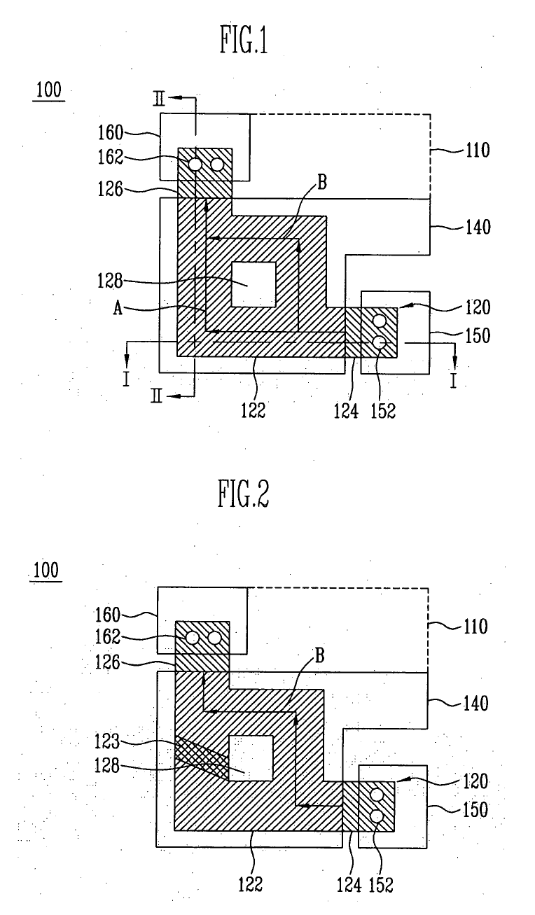

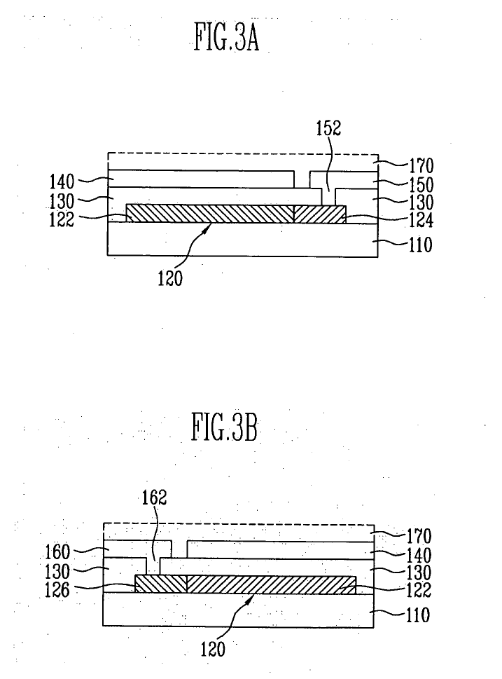

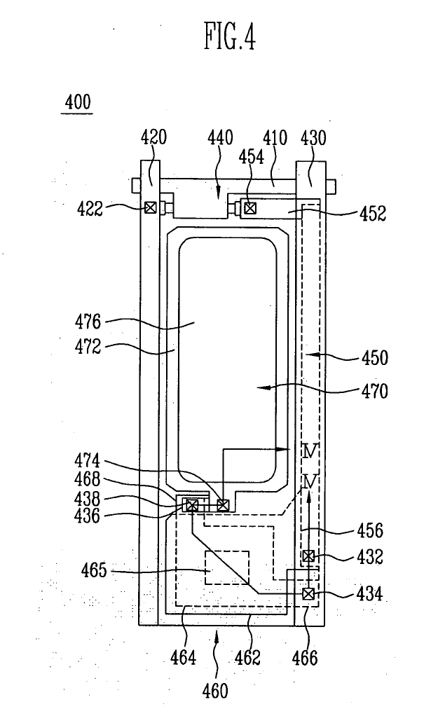

FIG. 1 is a plan view showing a driving transistor according to an exemplary embodiment of the present invention, FIG. 2 is a plan view showing the driving transistor of FIG. 1 with a defect in a channel region, FIG. 3A is a sectional view showing the driving transistor along line I-I of FIG. 1, and FIG. 3B is a sectional view showing the driving transistor along line II-II of FIG. 1.

Referring to FIG. 1, FIG. 2, FIG. 3A and FIG. 3B, a driving transistor 100 according to an exemplary embodiment of the present invention may comprise a semiconductor layer 120 formed on an insulating substrate 110, an insulating layer 130 formed on the semiconductor layer 120, and a gate electrode 140 facing a channel region 122 of the semiconductor layer 120 across the insulating layer 130. In other words, in the present exemplary embodiment, the channel region 122 may include the portion of the semiconductor layer 120 that is overlapped by the gate electrode 140. A predetermined current may flow through the channel region 122, which acts as a current path, of the driving transistor 100 according to a voltage applied to the gate electrode 140.

The semiconductor layer 120 may comprise the channel region 122, a source region 124, and a drain region 126. Here, the source region 124 and the drain region 126 may be swapped with each other. Further, the channel region 122 may be shaped like a rectangular ring. An insulating island 128 may be formed in the channel region 122 to divide the current path into at least two current paths A and B. The insulating island 128 may be formed by patterning a groove in the semiconductor layer 120 and then filling the groove with an insulating material. The insulating material may be any suitable insulating material, such as, for example, the material used for the insulating layer 130.

When the channel region 122 is formed in a rectangular ring shape as shown in FIG. 1, the source region 124 and the drain region 126 may be connected to two opposite comers of the channel region 122. For example, the source region 124 and the drain region 126 may be disposed having an angle of about 90 degrees and forming two vertical and horizontal current paths A and B. Alternatively, the drain region 126 could be connected to an upper left side of the channel region 122, rather than an upper top side of the channel region 122 as shown in FIG. 1. Similarly, the source region 124 could be connected to a lower bottom side of the channel region 122 rather than to a lower right side of the channel region 122 as shown in FIG. 1.

The insulating layer 130 may be formed on the semiconductor layer 120. The insulating layer 130 may be formed with first and second contact holes 152 and 162 exposing the source region 124 and the drain region 126, respectively. Further, the gate electrode 140, a source electrode 150 and a drain electrode 160 may be formed on the insulating layer 130. The source electrode 150 and the drain electrode 160 may be coupled to the source region 124 and the drain region 126 through the first and second contact holes 152 and 162, respectively. Here, a first end of the gate electrode 140 may face the channel region 122 with the insulating layer 130 interposed therebetween. Additionally, a protective layer or a dielectric layer 170 may be formed on the foregoing structure, as necessary.

With such a configuration, even though a defect may exist at a predetermined portion in the channel, the current of the driving transistor may remain substantially constant. That is, even though a defect 123 may negatively affect the current path A as shown in FIG. 2, the entire current may remain substantially constant through the other current path B.

In the foregoing embodiment, the TFT has a coplanar structure or an upper gate structure, but the present invention is not limited thereto. For example, the TFT may have a staggered structure or a lower gate structure. As described above, according to an exemplary embodiment of the present invention, an insulating island may be formed in the channel region to form at least two current paths in the channel, so that the entire current may remain substantially constant even though the ELA process causes a defect in the channel region.

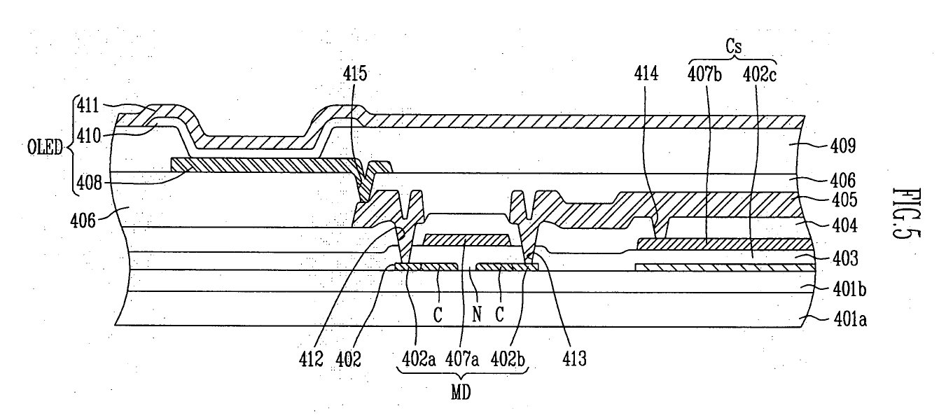

Hereinbelow, for example, a pixel structure for an organic light emitting display including the foregoing driving transistor will be described. FIG. 4 is a layout of a pixel comprising the driving transistor according to an exemplary embodiment of the present invention. For reference, a circuit diagram corresponding to the layout of FIG. 4 is shown in a pixel region of the organic light emitting display of FIG. 7.

Referring to FIG. 4, a pixel circuit 400 may comprise a switching transistor 440, a capacitor 450, a driving transistor 460, and an organic light-emitting device (OLED) 470. Here, a TFT may be used for the switching transistor 440 and the driving transistor 460, and each TFT has a gate, a source and a drain. Further, the capacitor 450 has a first terminal and a second terminal.

The switching transistor 440 may comprise the gate extending from a scan line 410, the source connected to a data line 420 through a first contact hole 422, and the drain connected to a first end of a lower electrode 452 of the capacitor 450 through a second contact hole 454. The switching transistor 440 samples a data signal transmitted to the data line 420 in response to a scan signal transmitted to the scan line 410.

The capacitor 450 may comprise an upper electrode 456, which is electrically connected to a power line 430 through a third contact hole 432, and the lower electrode 452, which may be patterned together with a semiconductor layer of the switching transistor 440. Here, the upper and lower electrodes 456 and 452 may be used as the first and second terminals of the capacitor 450, respectively. The capacitor 450 stores a voltage corresponding to the data signal transmitted to the data line 420 while the switching transistor 440 is turned on, and it maintains the stored voltage while the switching transistor 440 is turned off. Thus, the capacitor 450 may be programmed with gradation to be represented in the pixel circuit 400.

The driving transistor 460 may comprise a gate electrode 462, which may be electrically connected to a second end of the lower electrode 452, a channel region 464 shaped, for example, in a rectangular ring, a source region 466 electrically connected to the power line 430 through a fourth contact hole 434, and a drain region 468 electrically connected to a drain electrode 436 through a fifth contact hole 438. Here, the driving transistor 460 may supply a current corresponding to the voltage applied between the first and second terminals of the capacitor 450 to the organic light-emitting device 470.

The rectangular ring-shaped channel region 464 faces the gate electrode 462 across a predetermined insulating layer. An insulating island 465 may be formed in the channel region 464 to provide at least two current paths in the channel region. The insulating island 465 may be formed by patterning a groove in the semiconductor layer 120 and filling the groove with a gate insulating layer material. The insulating island 465 is not limited to a rectangular shape. For example, it may have various shapes such as an elliptical shape, a polygonal shape, in addition to the rectangular shape.

The rectangular ring-shaped channel region 464 has two opposite corners to which the source region 466 and the drain region 468 are connected. More specifically, the source region 466 and the drain region 468 may be disposed having an angle of about 90 degrees, thereby forming two vertical and horizontal current paths.

With this configuration, even if a defect forms at a predetermined portion on a current path in the channel region 464 of the driving transistor 460, the entire current may remain substantially constant and the uniformity of the driving transistor in the panel may be enhanced, thereby improving picture quality.

The OLED 470 may comprise a first electrode 472 electrically connected to the drain electrode 436 through a sixth contact hole 474, an organic thin film 476 formed on the first electrode 472, and a second electrode (not shown) formed on the organic thin film 476. Here, the first electrode 472 may act as an anode, and the second electrode 476 may act as a cathode, and the cathode may be formed of, for example, indium tin oxide (ITO).

The organic thin film 476 may be formed in a multi-layered structure including a hole injecting layer and an electron injecting layer at opposite sides of a light emitting layer, thereby enhancing injection of electrons and holes from the first and second electrodes. Further, the organic thin film 476 may also include an electron transporting layer, a hole transporting layer, and a hole blocking layer to enhance the OLED's light emission.

With this configuration, the OLED 470 emits light having a predetermined brightness that corresponds to the current applied by the driving transistor 460.

In the foregoing embodiment, the switching transistor and the driving transistor are P-type transistors, but they may also be N-type transistors.

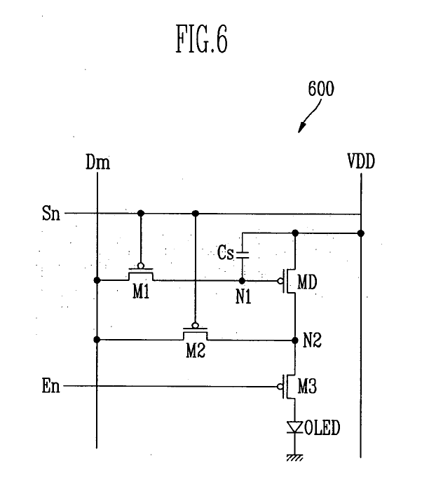

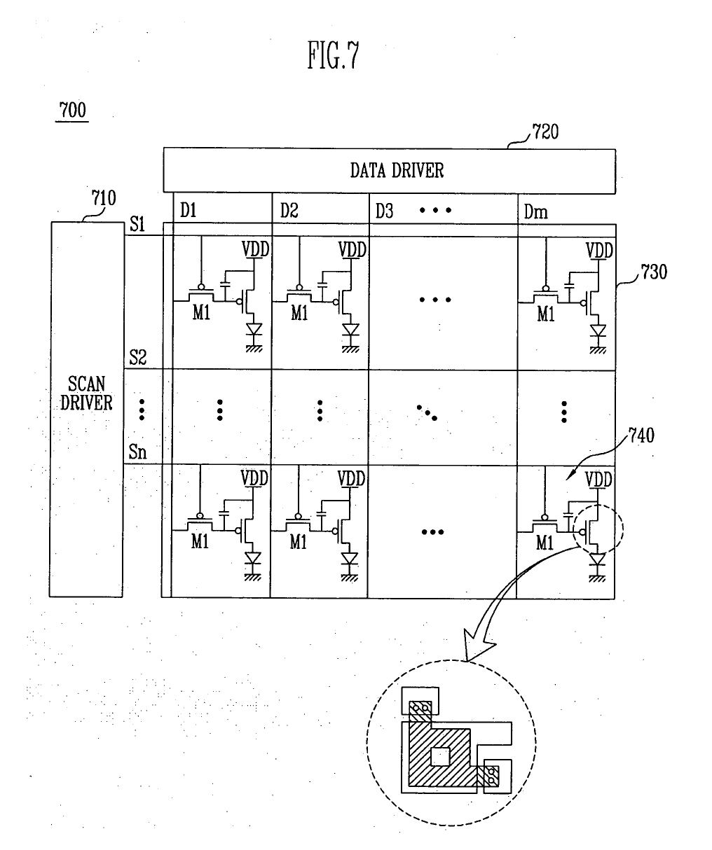

Further, in the foregoing embodiment, the pixel circuit 400 comprises one switching transistor and one driving transistor, but it is not limited thereto. For example, the pixel circuit may comprise at least two driving transistors or at least two switching transistors. Also, the pixel circuit may comprise at least two OLEDs connected to one driving transistor. In this case, the pixel circuit can be driven to sequentially operate two OLEDs, leaving a time lag therebetween. Further, the multiple OLEDs may display different colors from each other. Additionally, the pixel circuit may be designed to have other voltage programming structures, or it may have a current programming structure as well as the above-described voltage programming structure. Here, the pixel circuit having the current programming structure will be described below with reference to FIG. 6.

Hereinbelow, an exemplary embodiment of the present invention will be described with reference to FIG. 5, which is a sectional view of a pixel employing the transistor according to an exemplary embodiment of the present invention taken along line IV-IV of FIG. 4. Hereinbelow, the pixel comprises the OLED and the pixel circuit. In FIG. 5, reference numerals mostly indicate layers based on a fabricating process thereof. Hence, they do not correspond to the reference numerals of FIG. 4.

Referring to FIG. 5, in the sectional structure of a pixel comprising the transistor according to an exemplary embodiment of the present invention, a buffer layer 401b, which may be made of a nitride layer or an oxide layer, may be formed on an insulating substrate 401a, which may be made of glass or the like. The buffer layer 401b prevents impurities, such as a metal ion or the like, from diffusing into an active channel of a semiconductor layer. Here, the buffer layer 401b may be deposited by a chemical vapor deposition (CVD) method, a sputtering method, or other similar method.

Next, an amorphous silicon layer may be deposited on the buffer layer 401b by CVD, sputtering, or other deposition methods, and then heated at a temperature of about 430° C. to dehydrogenate the amorphous silicon layer. The dehydrogenated amorphous silicon layer may be crystallized through a predetermined process, thereby simultaneously forming a semiconductor layer 402 and a lower electrode 402c of a capacitor Cs.

Here, the amorphous silicon layer may be crystallized using, for example, solid phase crystallization (SPC), excimer laser crystallization (ELC), excimer laser annealing (ELA), sequential lateral solidification (SLS), metal induced crystallization (MIC), and metal induced lateral crystallization (MILC).

Then, the semiconductor layer 402 may be formed on a region of the substrate in which a channel region C is to be formed, and it may be patterned to include a rectangular ring-shape with a groove. At this time, the semiconductor layer 402 is patterned to form what will become the source region 402b and the drain region 402a at two opposite corners of the channel region C.

Then, a gate-insulating layer 403 may be deposited on the entire surface of the substrate 401a having the semiconductor layer 402, and a gate electrode material, such as aluminum, may be deposited on the entire surface of the gate insulating layer 403 and patterned to form a gate electrode 407a. An upper electrode 407b of the capacitor Cs may be simultaneously patterned with the gate electrode 407a. Predetermined impurities may then be ion-injected using the gate electrode 407a as a mask, thereby forming the source region 402b and the drain region 402a. Here, a portion of the semiconductor layer 402 that faces the gate electrode 407a across the gate insulating layer 403 may be used as the region in which the rectangular ring-shaped channel region C having an insulating island N is formed.

An interlaying insulating layer 404 may then be formed on the foregoing structure, and first and second contact holes 413 and 412 may be formed in the interlaying insulating layer 404 to expose a portion of the source region 402b and the drain region 402a, respectively. A third contact hole 414 may be simultaneously formed to expose a portion of the upper electrode 407b. Then, a metal layer 405 may be deposited on the entire substrate and patterned to form a source electrode and a drain electrode. The drain electrode and the source electrode may be electrically connected to the drain region 402a and the source region 402b through the first contact hole 412 and the second contact hole 413, respectively. The upper electrode 407b of the capacitor Cs may be electrically connected to the metal layer 405 through the third contact hole 414.

Then, the metal layer 405 may be covered with a protective layer 406. The protective layer 406 may be formed with a fourth contact hole 415 that exposes a portion of the drain electrode of the driving transistor MD. A lower electrode forming material may then be deposited and patterned on an upper portion of the protective layer 406 to form the lower electrode 408, which may act as an anode. The lower electrode 408 is electrically connected to the drain electrode through the fourth contact hole 415.

Then, a flattening layer 409 may be formed of an insulating material on the foregoing structure and patterned to form an opening exposing a portion of the lower electrode 408. Then, an organic light emission material may be formed in the opening, and an upper electrode 411 may be formed on the foregoing structure including the organic light emission material 410. The upper electrode may act as a cathode.

This configuration provides the driving transistor MD comprising the rectangular ring-shaped channel region, the source and the drain regions connected to have an angle of about 90 degrees to the channel region, and the gate electrode facing the channel across the gate insulating layer. Further, the capacitor Cs may be formed by the lower electrode and the upper electrode facing the lower electrode. Also, the organic light-emitting device (OLED) includes the lower electrode, the organic light emitting layer, and the upper electrode.

The above-described embodiment shows a method for fabricating the pixel comprising a PMOS TFT, but the invention is not limited thereto. For example, other TFT structures, such as an NMOS TFT or a CMOS TFT, may be used.

Further, in the above-described embodiment, the lower and upper electrodes of the capacitor Cs are formed simultaneously with the semiconductor layer and the gate electrode, respectively, but the present invention is not limited thereto. For example, the capacitor Cs may comprise a lower electrode formed of the same layer as the gate electrode and an upper electrode formed of the same layer as the source or drain electrode.

FIG. 6 is a circuit diagram showing another pixel comprising the driving transistor according to an exemplary embodiment of the present invention.

Referring to FIG. 6, a pixel circuit 600 may comprise a driving transistor MD, a capacitor Cs, and first through third switching transistors M1, M2 and M3. Here, the driving transistor MD and the first through third transistors M1, M2 and M3 comprise a gate, a source and a drain. Further, the capacitor Cs comprises a first terminal and a second terminal.

The first switching transistor M1 comprises the gate electrically connected to a first scan line Sn, the drain electrically connected to a first node N1, and the source electrically connected to a data line Dm. Here, the first switching transistor M1 charges the capacitor Cs with a voltage in response to a first scan signal applied to the first scan line Sn.

The second switching transistor M2 comprises the gate electrically connected to the first scan line Sn, the drain electrically connected to a second node N2, and the source electrically connected to the data line Dm. Here, the second switching transistor M2 supplies a data current flowing in the data line Dm to the driving transistor MD in response to the first scan signal applied to the first scan line Sn.

The third switching transistor M3 comprises the gate electrically connected to a second scan line En, the source electrically connected to the second node N2, and the drain electrically connected to an organic light emitting device OLED. The third switching transistor M3 supplies a current flowing in the driving transistor MD to the organic light emitting device OLED in response to a second scan signal applied to the second scan line En.

The capacitor Cs comprises the first terminal electrically connected to a power voltage VDD and the second terminal electrically connected to the first node N1. Here, the capacitor Cs stores the voltage corresponding to a data current for the driving transistor MD while the first and second switching transistors M1 and M2 are turned on. The voltage charged in the capacitor Cs corresponds to the quantity of electric charge of a voltage Vgs applied between the gate and the source electrodes of the driving transistor MD. Further, the capacitor Cs maintains the gate voltage of the driving transistor MD while the first and second switching transistors M1 and M2 are turned off.

The driving transistor MD comprises the gate electrode electrically connected to the first node N1, the source electrode to which the power voltage is applied, and the drain electrode connected to the second node N2. Here, the driving transistor MD supplies a current corresponding to the voltage applied between the first and second terminals of the capacitor Cs to the organic light emitting device OLED while the third switching transistor M3 is turned on.

Here, the driving transistor MD may comprise a rectangular ring-shaped channel region, the source region and the drain region connected to two opposite corners of the channel region, and the gate electrode facing the channel region across an insulating layer.

As described above, in an active matrix type display using a pixel circuit according to an exemplary embodiment of the present invention, even though a defect is formed in a predetermined portion of the channel region of the driving transistor, the entire current of the driving transistor may remain substantially constant. As discussed above, the present invention is applicable to a current programming type pixel circuit comprising a polysilicon TFT formed by crystallizing an amorphous silicon layer.

While exemplary embodiments of the present invention describe a pixel circuit for an organic light emitting display, the present invention is not limited thererto. For example, the present invention may be applicable to a display device, such as an active matrix type TFT liquid crystal display (LCD), a plasma display panel (PDP), or a field emission display (FED) using a driving TFT according to an exemplary embodiment of the present invention.

FIG. 7 is a schematic view showing an organic light emitting display comprising a driving TFT according to an exemplary embodiment of the present invention.

Referring to FIG. 7, an organic light emitting display 700 may comprise a scan driver 710, a data driver 720, and an image display part 730. The image display part 730 may comprise a plurality of pixels 740, and each pixel 740 may comprise a switching transistor M1, a capacitor Cs, a driving transistor MD, and an organic light emitting device OLED (see FIG. 6). Here, the driving transistor MD may have a rectangular ring-shaped channel region, a source is region and a drain region connected to two opposite comers of the channel region, and the gate electrode facing the channel across an insulating layer (refer to the enlarged view of FIG. 7).

Here, the driving transistor MD supplies a current corresponding to the voltage applied between the terminals of the capacitor Cs to the organic light emitting device OLED. The capacitor Cs is coupled between the source electrode and the gate electrode of the driving transistor MD, and it maintains data voltage applied by the switching transistor M1 for a predetermined period. With this configuration, when the switching transistor M1 turns on in response to the scan signal applied to its gate electrode, the data voltage applied through a data line Dm is stored in the capacitor Cs. Then, the switching transistor M1 turns off, and the driving transistor MD applies the current corresponding to the voltage stored in the capacitor Cs to the organic light emitting device OLED. Thus, the organic light emitting device OLED emits light with predetermined brightness corresponding to the applied current.

Further, the organic light emitting display 700 may comprise n×m pixels 740, n scan lines S1, S2, . . . , Sn extending horizontally, and m data lines D1, D2, D3 . . . , Dm extending vertically. The scan driver 710 may sequentially transmit a scan signal to the scan lines S1, S2, . . . Sn. The scan signal is transmitted to the pixel 740, the data driver 720 transmits a data signal to the data lines D1, D2, D3, . . . , Dm, and the data voltage is transmitted to the pixel 740.

The pixel 740 samples the data signal transmitted from the data driver 720 in response to the scan signal transmitted from the scan driver 710, and then represents a predetermined gray scale corresponding to the sampled data signal.

In the foregoing embodiment, the pixel circuit comprises one switching transistor and one driving transistor, but the present invention is not limited thereto. For example, the organic light emitting display may comprise a pixel circuit including at least two driving transistors or at least two switching transistors. Further, the organic light emitting display may comprise a pixel circuit including at least two organic light emitting devices connected to one driving transistor. In this case, the pixel circuit sequentially drives the two organic light-emitting devices, leaving a time lag in between. Also, the organic light-emitting device may comprise other voltage programming type pixel circuits and a current programming type pixel circuit.

As described above, the present invention provides a transistor, in which a current path may be altered from a defective channel to another channel of the TFT so that the entire current may remain substantially constant.

Additionally, a pixel circuit and a display device may be formed including a TFT formed with an insulating island in a channel region to enhance uniformity of the driving transistor, thereby improving picture quality.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A pixel circuit of an organic light emitting display, comprising:
a first switching device transmitting a data signal in response to a selection signal;
a storage capacitor storing a voltage corresponding to the transmitted data signal; and
a driving transistor supplying a current corresponding to the voltage stored in the storage capacitor for driving an organic light emitting device,
wherein the driving transistor comprises:
a semiconductor layer including a substantially rectangular ring-shaped channel region and a source region and a drain region connected to opposite comers of the channel region, respectively; and
a gate electrode facing the channel region across an insulating layer.

2. The pixel circuit of claim 1, wherein the semiconductor layer comprises a polycrystalline silicon layer.

3. The pixel circuit of claim 2, wherein the polycrystalline silicon layer is formed by a process of crystallizing an amorphous silicon layer.

4. The pixel circuit of claim 3, wherein the process of crystallizing the amorphous silicon layer includes an excimer laser annealing process.

5. The pixel circuit of claim 1, wherein the channel region comprises two current paths formed between the source region and the drain region.

6. The pixel circuit of claim 1, wherein the data signal is a voltage signal or a current signal.

7. An organic light emitting display, comprising:
a data line to transmit a data signal;
a scan line to transmit a selection signal; and
a pixel circuit formed in a region defined by two adjacent data lines and two adjacent scan lines, the pixel circuit including a first switching device transmitting the data signal in response to the selection signal, a storage capacitor storing a voltage corresponding to the transmitted data signal, and a driving transistor supplying a current corresponding to the voltage stored in the storage capacitor for driving an organic light emitting device,
wherein the driving transistor comprises:
a semiconductor layer including a substantially rectangular ring-shaped channel region and a source region and a drain region connected to opposite comers of the channel region, respectively, and
a gate electrode facing the channel region across an insulating layer.

8. The organic light emitting display of claim 7, wherein the semiconductor layer comprises a polycrystalline silicon layer.

9. The organic light emitting display of claim 8, wherein the polycrystalline silicon layer is formed by a process of crystallizing an amorphous silicon layer.

10. The organic light emitting display of claim 9, wherein the process of crystallizing the amorphous silicon layer includes an excimer laser annealing process.

11. The organic light emitting display of claim 7, wherein the channel region comprises two current paths formed between the source region and the drain region.

12. The organic light emitting display of claim 7, wherein the data signal is a voltage signal or a current signal.

13. A transistor, comprising:
a semiconductor layer on a substrate and including a substantially rectangular ring-shaped channel region, and a source region and a drain region connected to opposite corners of the channel region, respectively;
an insulating layer contacting the channel region; and
a gate electrode facing the channel region across the insulating layer.

14. The transistor of claim 13, wherein the semiconductor layer comprises a polycrystalline silicon layer.

15. The transistor of claim 14, wherein the polycrystalline silicon layer is formed by a process of crystallizing an amorphous silicon layer.

16. The transistor of claim 15, wherein the process of crystallizing the amorphous silicon layer includes an excimer laser annealing process.

17. The transistor of claim 13, wherein the channel region comprises two current paths formed between the source region and the drain region.

18. A display device comprising the transistor of claim 13.

19. The display device of claim 18, wherein the display device is an electroluminescent display, a liquid crystal display, a plasma display panel, or a field emission display.
